(19) United States
(12) Patent Application Publication
(10) Pub. No.: US 2025/0258239 A1
(43) Pub. Date: Aug. 14, 2025

(54) Standby Energy System

(71) Applicant: Standby Energy, Inc, Tomball, TX (US)

(72) Inventor: Oguz Murtezaoglu, Tomball, TX (US)

(21) Appl. No.: 19/050,081

(22) Filed: Feb. 10, 2025

Related U.S. Application Data
(60) Provisional application No. 63/551,729, filed on Feb. 9, 2024.

(51) Int. Cl. G01R 31/3842; G01R 31/36; G01R 31/371; G01R 31/396; G01R 31/40

(52) U.S. Cl. CPC G01R 31/3842; G01R 31/3646; G01R 31/371; G01R 31/396; G01R 31/40

(57) ABSTRACT

A BMARS system for maintaining and managing battery performance. The term BMARS stands for battery monitoring and recharge system. A BMARS control module configured to monitor, log, and manage one or more battery parameters, a charger adapted to convert AC power to DC power, a direct current power connected to the charger and adapted to supply DC power to at least one load, a breaker interposed between the direct current power and one or more batteries one or more batteries, a battery safety switch housed in a safety enclosure, one or more sensors one or more sensors configured to measure voltage, temperature, or current of the one or more batteries, and a control panel communicatively coupled to the BMARS control module.

### CROSS-REFERENCE TO RELATED APPLICATIONS

This application claims benefit to and incorporates by reference, U.S. provisional patent application No. 63/551,729 filed on 2024 Feb. 9.

### STATEMENT REGARDING FEDERALLY SPONSORED RESEARCH OR DEVELOPMENT (IF APPLICABLE)

Not applicable.

### REFERENCE TO SEQUENCE LISTING, A TABLE, OR A COMPUTER PROGRAM LISTING COMPACT DISC APPENDIX (IF APPLICABLE)

Not applicable.

### BACKGROUND OF THE INVENTION

### Field of the Invention

The present invention relates to battery monitoring and management systems (“BMARS”), specifically to systems designed to continuously monitor, log, and manage battery performance to ensure optimal operation, longevity, and reliability. The system further provides real-time data and remote-control capabilities, enabling proactive battery maintenance and emergency response.

### Background of the Invention

Modern electrical infrastructure relies heavily on stable and reliable power sources, with batteries serving as critical backup power supplies in industrial, commercial, and residential applications. Utility power grids face increasing complexity due to longer transmission distances, varying customer loads, power surges, electrical noise, adverse weather conditions, and unexpected equipment failures. These factors can lead to power interruptions, making reliable battery systems essential for ensuring continued operation of critical systems.

Despite the widespread use of backup batteries, traditional monitoring solutions often fail to provide real-time insights into battery health and performance. Conventional battery monitoring systems primarily alert users after a battery failure has occurred, offering little opportunity for proactive maintenance. As a result, operators are often unable to address battery degradation in advance, leading to unexpected failures and potential downtime. This limitation is particularly problematic in industries where uninterrupted power is crucial, such as telecommunications, data centers, and industrial control systems.

To address these shortcomings, the present invention introduces an advanced Battery Monitor and Recharge System (BMARS). BMARS continuously monitors individual battery cells 24/7/365, recording critical parameters such as voltage, temperature, charge/discharge currents, and overall capacity. Unlike conventional systems, BMARS does not merely indicate battery failure but provides real-time diagnostics and long-term performance tracking, allowing users to identify and resolve potential issues before a failure occurs.

The system enables remote monitoring and control via communication interfaces such as Modbus, allowing operators to adjust charging states, trigger equalization cycles, and optimize battery health from a centralized location. Additionally, BMARS integrates an automated alert system, providing immediate warnings for abnormal conditions and facilitating timely corrective actions. The system maintains a rolling three-year data log, ensuring comprehensive historical analysis and compliance with maintenance protocols.

By implementing the BMARS system, operators can extend battery lifespan, reduce maintenance costs, and prevent unexpected power failures. The invention provides a significant advancement over existing solutions by offering a proactive, intelligent approach to battery monitoring and management.

### BRIEF SUMMARY OF THE INVENTION

A BMARS system for maintaining and managing battery performance. The term BMARS stands for battery monitoring and recharge system. Said BMARS system comprising a BMARS control module configured to monitor, log, and manage one or more battery parameters, a charger adapted to convert AC power to DC power, a direct current power connected to said charger and adapted to supply DC power to at least one load, a breaker interposed between said direct current power and one or more batteries one or more batteries, a battery safety switch housed in a safety enclosure, one or more sensors one or more sensors configured to measure voltage, temperature, or current of said one or more batteries, and a control panel communicatively coupled to said BMARS control module. Wherein said BMARS control module is configured to: (a) automatically track a charging state of said one or more batteries, (b) selectively switch between a Float mode and an Equalize mode for said charger, (c) record performance data for said one or more batteries at predefined time intervals, and (d) provide remote monitoring and control signals for battery maintenance. Said BMARS control module comprises an address space having: one or more processors, communication hardware, and a memory storing instructions for a device application, an alarm system application, and a notification system application. Said communication hardware is configured to exchange data with an external network, and said alarm system application is programmed to generate an alarm upon detecting abnormal battery conditions selected from the group consisting of: over-voltage, under-voltage, over-temperature, and under-temperature. Said BMARS system further comprises a hall effects sensor included among said one or more sensors, the hall effects sensor being arranged to measure both charging current flowing from said charger to said one or more batteries and load current drawn from said one or more batteries to said direct current power.

The BMARS system for maintaining and managing battery performance. The term BMARS stands for battery monitoring and recharge system. Said BMARS system comprising the BMARS control module configured to monitor, log, and manage one or more battery parameters, the charger adapted to convert AC power to DC power, the direct current power connected to said charger and adapted to supply DC power to at least one load, the breaker interposed between said direct current power and one or more batteries one or more batteries, the battery safety switch housed in the safety enclosure, one or more sensors one or more sensors configured to measure voltage, temperature, or current of said one or more batteries, and the control panel communicatively coupled to said BMARS control module. Wherein said BMARS control module is configured to: (a) automatically track a charging state of said one or more batteries, (b) selectively switch between a Float mode and an Equalize mode for said charger, (c) record performance data for said one or more batteries at predefined time intervals, and (d) provide remote monitoring and control signals for battery maintenance.

A method of use for operating the BMARS system is disclosed. Comprising (a) initializing a battery monitoring step to activate real-time tracking of battery parameters for one or more batteries one or more batteries, (b) monitoring said battery parameters at a monitoring battery parameters step, the battery parameters including at least one of voltage, temperature, and current, (c) determining whether said one or more batteries require charging at a determining charging status step, (d) triggering a triggering charging mode adjustment step to place the charger in either Float mode or Equalize mode based on a condition of said one or more batteries, (e) continuing an equalization process at a continuing equalization step until said one or more batteries reach full charge, and (f) conducting a battery load test to evaluate discharge response of said one or more batteries, wherein data from steps (b) through (f) is logged at predefined time intervals and stored for subsequent analysis.

### BRIEF DESCRIPTION OF THE SEVERAL VIEWS OF THE DRAWING

FIG. 1 illustrates a diagram of a BMARS system 100.

FIG. 2 illustrates a wiring harness 200.

FIG. 3 illustrates an exemplary installation configuration 300 of said BMARS system 100.

FIG. 4 illustrates a detailed view of said exemplary installation configuration 300.

FIG. 5 illustrates a software interface 500 of said BMARS system 100.

FIG. 6 illustrates a battery status screen 600 within said software interface 500.

FIG. 7 illustrates a method of use 700 of said BMARS system 100.

FIG. 8 illustrates a block diagram of an address space 800 within said BMARS control module 104.

FIGS. 9 and 10 illustrate a battery discharge test 900 and a battery condition status readout 1000, respectively.

### DETAILED DESCRIPTION OF THE INVENTION

The following description is presented to enable any person skilled in the art to make and use the invention as claimed and is provided in the context of the particular examples discussed below, variations of which will be readily apparent to those skilled in the art. In the interest of clarity, not all features of an actual implementation are described in this specification. It will be appreciated that in the development of any such actual implementation (as in any development project), design decisions must be made to achieve the designers' specific goals (e.g., compliance with system-and business-related constraints), and that these goals will vary from one implementation to another. It will also be appreciated that such development effort might be complex and time-consuming, but would nevertheless be a routine undertaking for those of ordinary skill in the field of the appropriate art having the benefit of this disclosure. Accordingly, the claims appended hereto are not intended to be limited by the disclosed embodiments, but are to be accorded their widest scope consistent with the principles and features disclosed herein.

This disclosure will refer to a “Battery Monitor and Recharge System” as a “BMARS”.

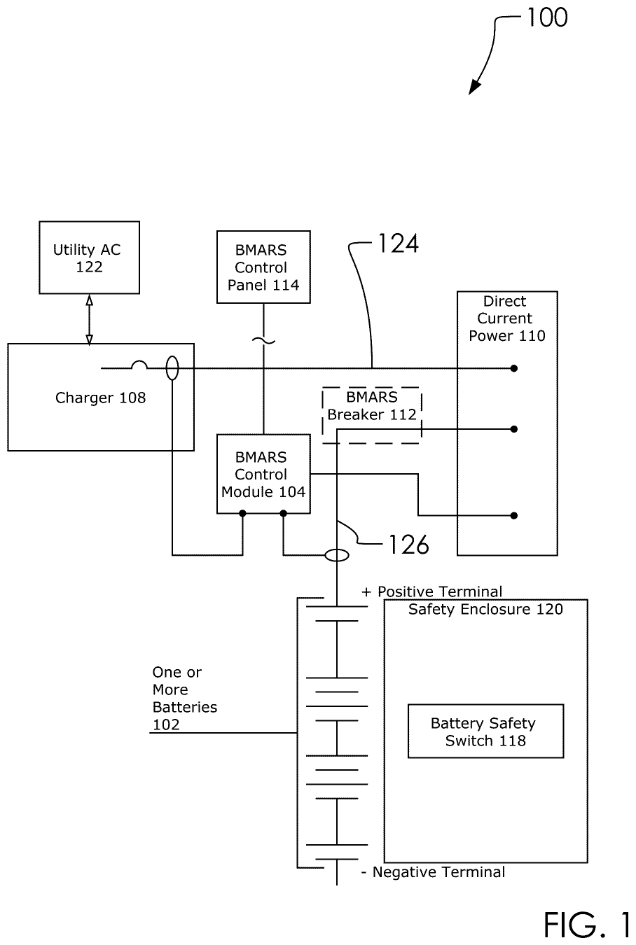

FIG. 1 illustrates a diagram of a BMARS system 100.

In one embodiment, said BMARS system 100 can be configured to manage and monitor one or more batteries 102 in conjunction with a direct current power 110, and a charger 108.

In one embodiment, said BMARS system 100 can comprise a BMARS control module 104, a breaker 112, a control panel 114, one or more sensors 116, and a battery safety switch 118.

Note that said direct current power 110 can also be referred to as a DCP-1 in this discussion.

In one embodiment, said battery safety switch 118 can interface with said one or more batteries 102 in a safety enclosure 120. In some implementations, said safety enclosure 120 can correspond to a “One Safety SW Enclosure” referenced in external documentation.

In one embodiment, said BMARS system 100 can be configured to monitor battery cells with little to no downtime. Wherein said BMARS system 100 can be configured for: logging critical data multiple times per minute (such as every 10 seconds), and allowing for real-time maintenance and correction actions. This ensures prolonged battery life and serviceability from remote locations.

In one embodiment, said BMARS system 100 can be configured to work with the charger 108, the direct current power 110, said one or more batteries 102 and the breaker 112. Wherein, said charger 108 can be configured for converting AC power to DC power to charge the battery. The charger operates in two modes: ‘Float’ for regular charging and maintaining the battery's charge level, and ‘Equalize’ for balancing the charge across all cells in the battery to ensure each cell is fully charged.

Said direct current power 110, or “DCP”, can comprise the DC power supply system that powers the station's loads. The DCP receives power from the charger and, in the event of a charger malfunction or utility outage, directly from the battery. Said one or more batteries 102 can store electrical energy in the form of DC power.

In one embodiment, said BMARS system 100 can monitor each cell within said one or more batteries 102 to ensure they are in good condition, charged correctly, and available to supply power whenever needed.

Said breaker 112, or “BMARS Breaker” can act as a breaker or switch that manages the connection between the battery, charger, and loads. It can be employed for monitoring the battery's state, including its charge level and health, and controls the charging mode (Float or Equalize) based on the battery's condition.

In one embodiment, said direct current power 110 can receive an utility AC input 122. Said direct current power 110 can be connected to said charger 108 with a DC bus 124. Said one or more batteries 102 can be connected to said direct current power 110 through said breaker 112. Said DC bus 124 and a second conductor 126 can each function as a bus or common conductor for distributing DC power among said charger 108, said BMARS control module 104, and said one or more batteries 102. In one embodiment, one or more hall effects sensors are looped around these bus lines to measure both charge current (flowing from said charger 108 to said one or more batteries 102) and load current (supplying said direct current power 110).

Said BMARS control module 104 can be configured to sense battery voltage, current, temperature, etc. In addition, said BMARS control module 104 can determine power flow direction, allowing real-time logging of both charging and discharging currents. Further said BMARS control module 104 can be configured to switch modes between Float and Equalize as described herein.

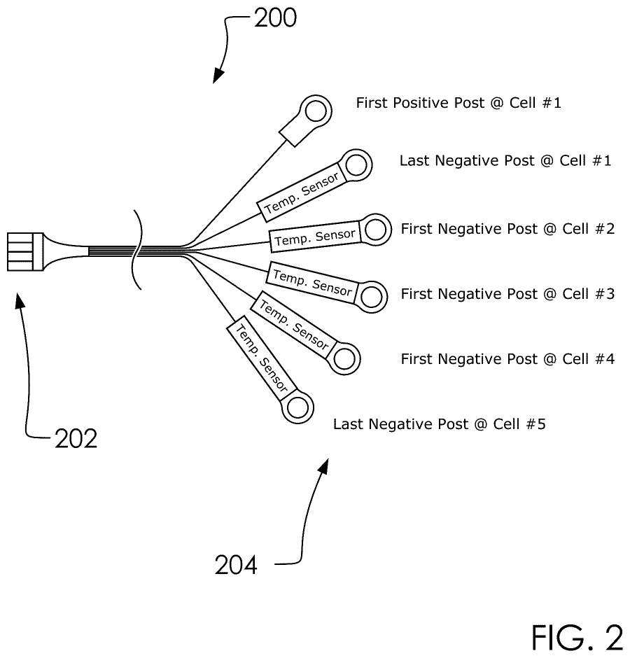

FIG. 2 illustrates a wiring harness 200.

Said wiring harness 200 can comprise a connector 202 and one or more posts 204.

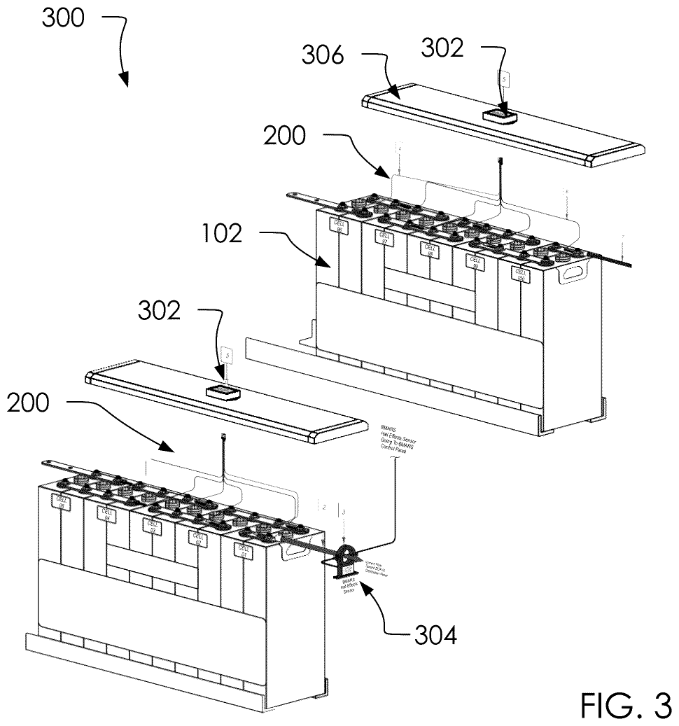

FIG. 3 illustrates an exemplary installation configuration 300 of said BMARS system 100.

Said BMARS system 100 can further comprise the BMARS control module 104, a hall effects sensor 304 and a battery cover 306, as illustrated. In one embodiment, said one or more sensors 116 can comprise at least said hall effects sensor 304.

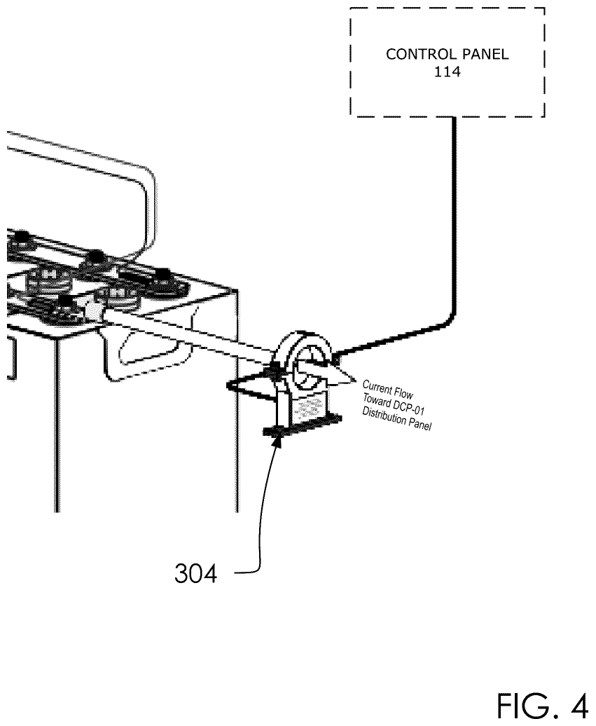

FIG. 4 illustrates a detailed view of said exemplary installation configuration 300.

Said hall effects sensor 304 can be affixed around relevant DC conductors (e.g., between said charger 108 and said direct current power 110, or between said direct current power 110 and said one or more batteries 102) to measure current in either direction.

In one embodiment, said hall effects sensor 304 can be in data communication with the control panel 114.

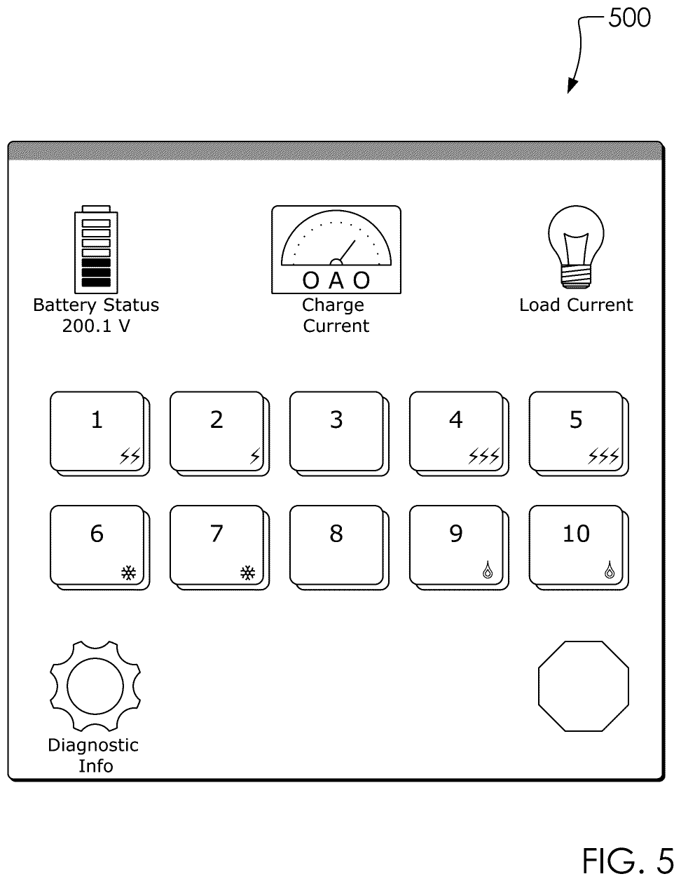

FIG. 5 illustrates a software interface 500 of said BMARS system 100.

In one embodiment, said software interface 500 can display a series of numeric readouts (e.g., cell voltages 1-n, charge current, load current, and temperature values), along with selectable buttons for initiating an equalization cycle or a battery load test. A data-download option can generate files containing timestamped voltage, current, and temperature logs for up to three years of operation.

Said BMARS system 100 can comprise said software interface 500; wherein said software interface 500 can comprise features include real-time displays of battery status, charge and load currents, cell states (with voltage and temperature indicators), and the ability to download logged data for analysis.

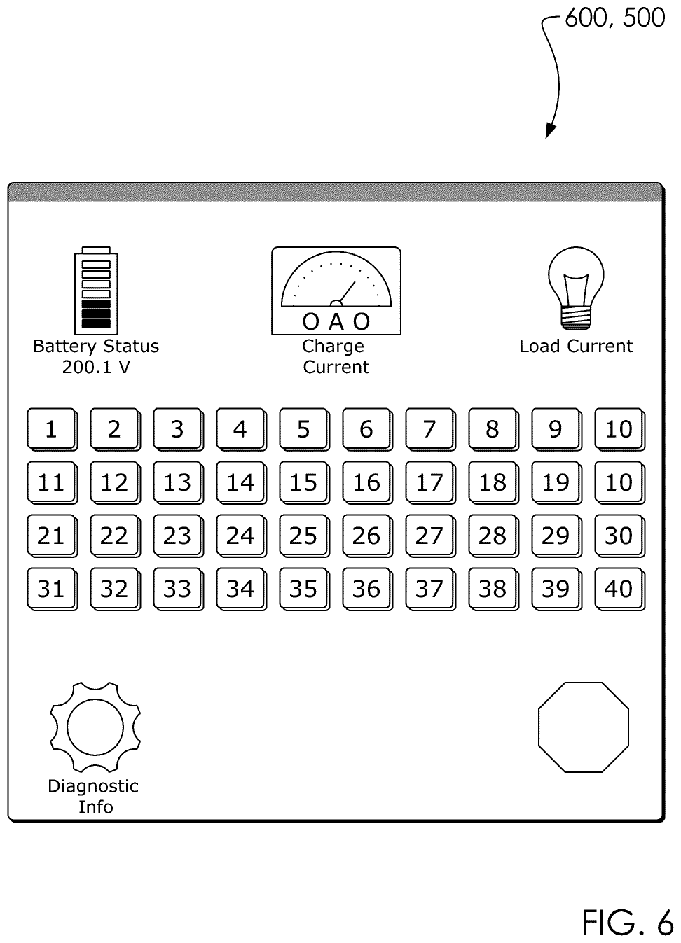

FIG. 6 illustrates a battery status screen 600 within said software interface 500.

Battery Service and Maintenance: said BMARS system 100 can be configured to extend the service life of said one or more batteries 102 by monitoring and maintaining battery and cell health in real-time, capable of logging critical data points at frequent intervals, such as every 10 seconds.

Remote Monitoring and Control: said BMARS system 100 can be configured with said communication hardware 804 for remote monitoring and control, allowing users to manage battery charge levels remotely, especially useful in preparation for anticipated events like hurricanes.

Battery Load Test Anytime: said BMARS system 100 can be equipped with a battery load test 712 feature, enabling users to conduct battery load tests whenever needed to ensure that said one or more batteries 102 maintain their optimal condition. In some implementations, said battery load test 712 can be triggered during normal operation without requiring the entire system to shut down.

Alarm System and Data Logging: said BMARS system 100 can be configured for advanced alarm and data logging functionalities, alerting users to conditions of concern and logging detailed data with date and time stamps for easy tracking and analysis of battery health.

Utility Outage Response: said BMARS system 100 can automatically switch to supply power directly from said one or more batteries 102 to said direct current power 110 without manual intervention during a utility outage, ensuring an uninterrupted power supply.

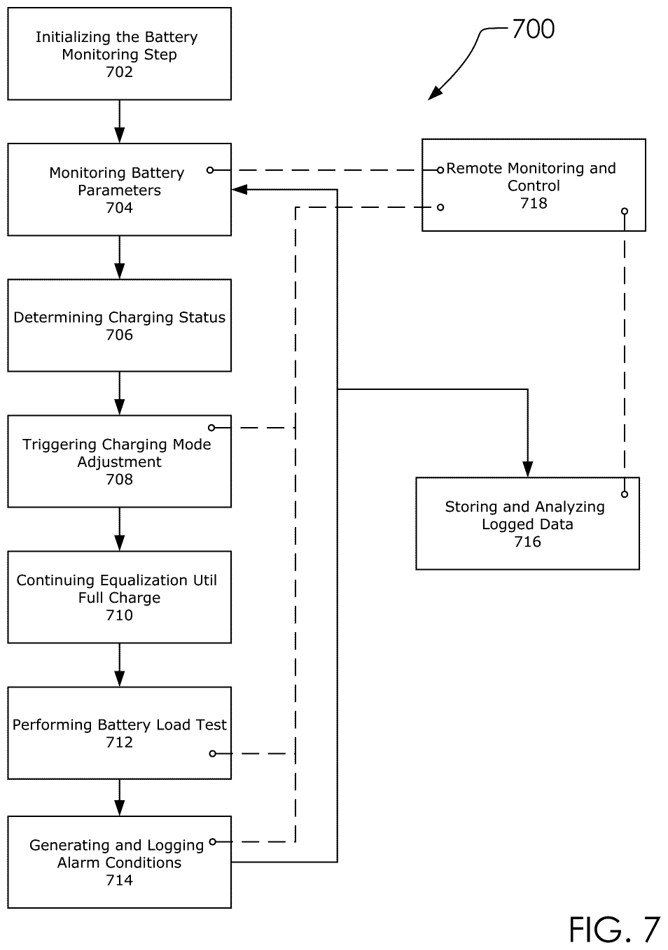

Installation and AH Capacity Determination: said BMARS system 100 can allow operators to either input the battery's AH rating or determine it through said battery load test 712 during the initial setup, facilitating accurate monitoring and maintenance right from the beginning. FIG. 7 illustrates a method of use 700 of said BMARS system 100.

In one embodiment, said method of use 700 can comprise initializing a battery monitoring step 702, wherein said BMARS system 100 is activated to begin real-time monitoring of said one or more batteries 102.

Following initialization, said BMARS system 100 proceeds to a monitoring battery parameters step 704, wherein said one or more sensors 116 continuously track voltage, temperature, and charge/discharge currents. Data acquired during this step is transmitted for further analysis and logging.

In one embodiment, said BMARS system 100 executes a determining charging status step 706, wherein said BMARS control module 104 evaluates whether said one or more batteries 102 require charging. If charging is required, said BMARS system 100 proceeds to a triggering charging mode adjustment step 708, wherein said charger 108 transitions between ‘Float’ mode and ‘Equalize’ mode based on the charging requirements.

Once charging mode adjustments are triggered, said BMARS system 100 facilitates a continuing equalization step 710 until full charge. In this step, said charger 108 maintains the ‘Equalize’ mode to balance charge levels across all battery cells, ensuring uniform capacity retention.

After achieving full charge, said BMARS system 100 can execute the battery load test 712, wherein said battery load test 712 is initiated to assess the discharge response and capacity of said one or more batteries 102. Said battery load test 712 can be executed at operator discretion, even if the system remains online, to confirm battery readiness.

In the event of detected anomalies or performance degradation, said BMARS system 100 can execute generating and logging alarm conditions 714. In this step, abnormal conditions such as excessive voltage drops, overheating, or irregular charge patterns are recorded with timestamped logs.

Said BMARS system 100 is further configured for a storing and analyzing logged data step 716, wherein historical battery performance data is retained for predictive maintenance, compliance reporting, and troubleshooting purposes. one embodiment, about three years of rolling data can be stored, capturing voltage, current, and temperature readings, along with event logs for each alarm or test performed.

In one embodiment, said BMARS system 100 supports a remotely monitoring and control step 718, allowing users to access real-time battery status, issue control commands, and adjust charging parameters via a wireless or wired communication interface. Data from said remotely monitoring and control step 718 is integrated into said storing and analyzing logged data step 716 to ensure continuous performance tracking.

Said BMARS system 100 can be further configured to manage operation modes of said charger 108, for example as between ‘Float’ and ‘Equalize’ based on the charge status of said one or more batteries 102 to ensure optimal charging and prevent potential battery damage due to overcharging or undercharging.

In one embodiment, said BMARS system 100 can further comprise AH Capacity Management; wherein, said BMARS system 100 can ensure that when a charge level of said one or more batteries 102 falls below 80%, said charger 108 is activated in ‘Float’ mode until reaching 80% charge, subsequently switching to ‘Equalize’ mode until full charge is achieved, thereafter maintaining ‘Float’ mode to avoid overcharging.

In one embodiment, said BMARS system 100 includes said communication hardware 804, enabling remote monitoring and control over said one or more batteries 102, facilitating battery load tests, and full recharging capabilities remotely in preparation for events such as hurricanes. This ensures a remote monitoring of said BMARS system 100.

Said BMARS system 100 can further comprise critical data logging; wherein, said BMARS system 100 can be equipped with functionality for logging critical data of said one or more batteries 102 including voltage, temperature, and charge/discharge currents, every 10 seconds, thus allowing for real-time maintenance and historical data analysis.

Said BMARS system 100 can further comprise a utility outage response; wherein: during a utility outage, said BMARS system 100 can automatically transition to supply power directly from said one or more batteries 102 to said direct current power 110 without manual intervention, ensuring uninterrupted power supply.

Said BMARS system 100 can be configured for alarm and data logging; wherein said BMARS system 100 can be capable of alarming under conditions of concern and logs data with precise date and time stamps for said one or more batteries 102, with about three years of rolling data storage, which can be downloaded for permanent record-keeping.

Said BMARS system 100 can further comprise battery load test recommendations; wherein, concurrent with conducting said battery load test 712, said BMARS system 100 can advise switching said charger 108 to ‘Equalize’ mode for a designated period before returning to ‘Float’ mode, ensuring that said one or more batteries 102 are in optimal condition for accurate testing.

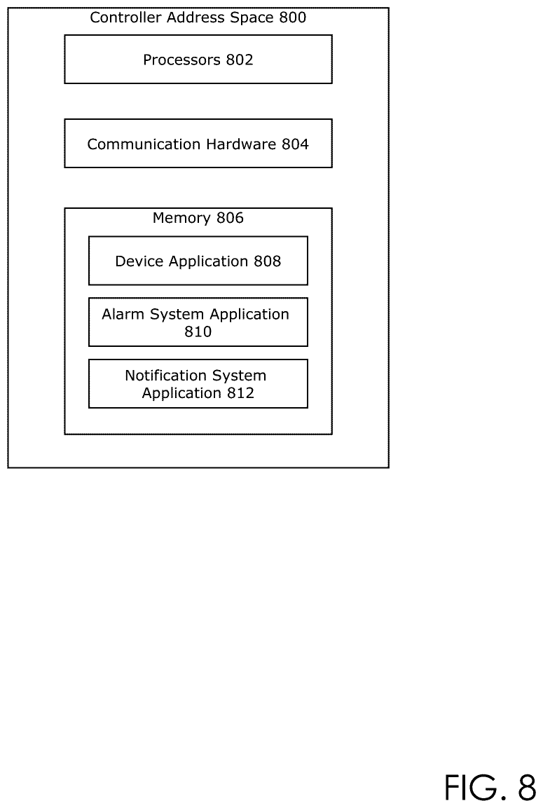

FIG. 8 illustrates a block diagram of an address space 800 within said BMARS control module 104.

Said address space 800 can comprise one or more processors 802, the communication hardware 804, a memory 806 having a device application 808, an alarm system application 810 and a notification system application 812.

As is known in the art, programs stored in said memory 806 can be run in said one or more processors 802. Further said communication hardware 804 can be in data communication with other computers, servers, IOT devices, or similar. Likewise, said communication hardware 804 can receive signals form said one or more sensors 116.

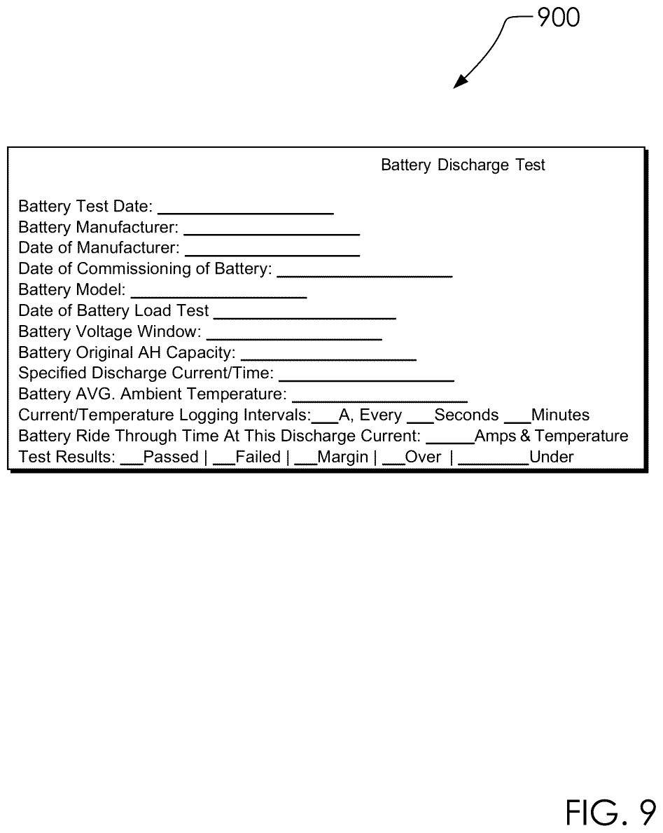

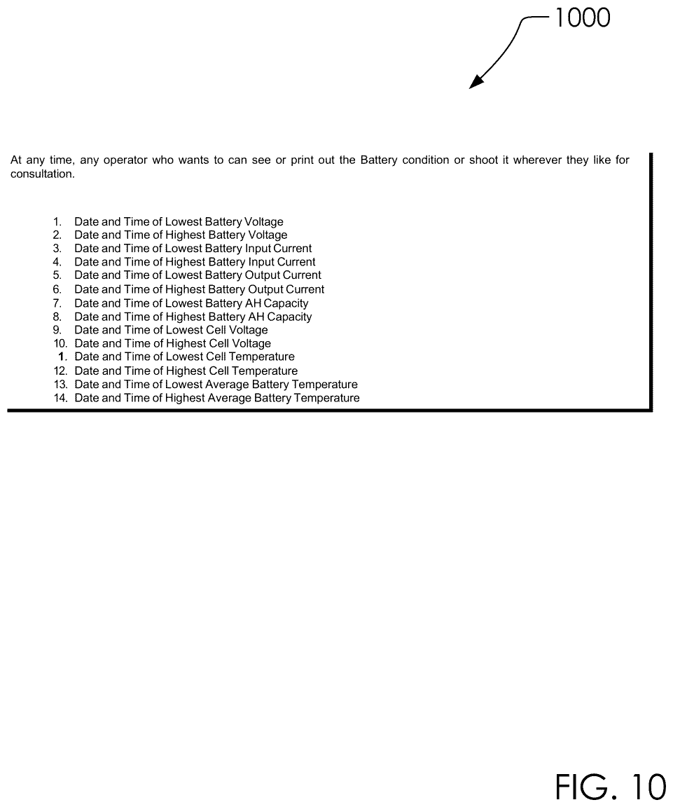

FIGS. 9 and 10 illustrate a battery discharge test 900 and a battery condition status readout 1000, respectively.

In one embodiment, said battery discharge test 900 can include displaying real-time cell voltages, discharge currents, and overall battery capacity in an on-screen or downloadable format, while said battery condition status readout 1000 can provide a historical log and present snapshot of voltages, temperatures, and alarm events over a three-year rolling period.

### Parts List

BMARS system 100,
one or more batteries 102,
BMARS control module 104,
charger 108,
direct current power 110,
breaker 112,
control panel 114,
one or more sensors 116,
battery safety switch 118,
safety enclosure 120,
wiring harness 200,
connector 202,
one or more posts 204,
exemplary installation configuration 300,
hall effects sensor 304,
battery cover 306,
software interface 500,
battery status screen 600,
method of use 700,
battery monitoring step 702,
monitoring battery parameters step 704,
determining charging status step 706,
triggering charging mode adjustment step 708,
continuing equalization step 710,
battery load test 712,
alarm conditions 714,
storing and analyzing logged data step 716,
remotely monitoring and control step 718,
address space 800,
one or more processors 802,
communication hardware 804,
memory 806,
device application 808,
alarm system application 810,
notification system application 812,
battery discharge test 900, and
battery condition status readout 1000.

The following section of the detailed description includes all embodiments from the original claims:

The BMARS system 100 for maintaining and managing battery performance. The term BMARS stands for battery monitoring and recharge system. Said BMARS system 100 comprising the BMARS control module 104 configured to monitor, log, and manage one or more battery parameters, the charger 108 adapted to convert AC power to DC power, the direct current power 110 connected to said charger 108 and adapted to supply DC power to at least one load, the breaker 112 interposed between said direct current power 110 and one or more batteries one or more batteries 102, the battery safety switch 118 housed in the safety enclosure 120, one or more sensors one or more sensors 116 configured to measure voltage, temperature, or current of said one or more batteries 102, and the control panel 114 communicatively coupled to said BMARS control module 104. Wherein said BMARS control module 104 can be configured to: (a) automatically track a charging state of said one or more batteries 102, (b) selectively switch between a Float mode and an Equalize mode for said charger 108, (c) record performance data for said one or more batteries 102 at predefined time intervals, and (d) provide remote monitoring and control signals for battery maintenance. Said BMARS control module 104 comprises the address space 800 having: one or more processors 802, communication hardware 804, and the memory 806 storing instructions for the device application 808, the alarm system application 810, and the notification system application 812. Said communication hardware 804 can be configured to exchange data with an external network, and said alarm system application 810 can be programmed to generate an alarm upon detecting abnormal battery conditions selected from the group consisting of: over-voltage, under-voltage, over-temperature, and under-temperature. Said BMARS system 100 further comprises the hall effects sensor 304 included among said one or more sensors 116, the hall effects sensor 304 being arranged to measure both charging current flowing from said charger 108 to said one or more batteries 102 and load current drawn from said one or more batteries 102 to said direct current power 110.

The BMARS system 100 for maintaining and managing battery performance. The term BMARS stands for battery monitoring and recharge system. Said BMARS system 100 comprising the BMARS control module 104 configured to monitor, log, and manage one or more battery parameters, the charger 108 adapted to convert AC power to DC power, the direct current power 110 connected to said charger 108 and adapted to supply DC power to at least one load, the breaker 112 interposed between said direct current power 110 and one or more batteries one or more batteries 102, the battery safety switch 118 housed in the safety enclosure 120, one or more sensors one or more sensors 116 configured to measure voltage, temperature, or current of said one or more batteries 102, and the control panel 114 communicatively coupled to said BMARS control module 104. Wherein said BMARS control module 104 can be configured to: (a) automatically track a charging state of said one or more batteries 102, (b) selectively switch between a Float mode and an Equalize mode for said charger 108, (c) record performance data for said one or more batteries 102 at predefined time intervals, and (d) provide remote monitoring and control signals for battery maintenance.

Said BMARS control module 104 comprises the address space 800 having: one or more processors 802, communication hardware 804, and The memory 806 storing instructions for The device application 808, the alarm system application 810, and The notification system application 812. Said communication hardware 804 can be configured to exchange data with an external network, and said alarm system application 810 can be programmed to generate an alarm upon detecting abnormal battery conditions selected from the group consisting of: over-voltage, under-voltage, over-temperature, and under-temperature.

Said BMARS system 100 further comprises the software interface 500, said software interface 500 presenting real-time graphical displays of battery status, cell voltages, cell temperatures, charge current, and load current.

Said software interface 500 includes the battery status screen 600 adapted to show a user-selectable option for initiating a battery load test and retrieving logged performance data.

Said BMARS system 100 further comprises the hall effects sensor 304 included among said one or more sensors 116, the hall effects sensor 304 being arranged to measure both charging current flowing from said charger 108 to said one or more batteries 102 and load current drawn from said one or more batteries 102 to said direct current power 110.

The rolling data comprising timestamped measurements of voltage, temperature, and charge or discharge current.

Said BMARS control module 104 can be configured to maintain about three years of rolling data for said one or more batteries 102,

Said BMARS control module 104 can be configured for performing the battery load test 712 on said one or more batteries 102 at any point during normal operation, and thereby assessing the available capacity of each battery cell without interrupting power to said direct current power 110.

Said battery safety switch 118 can be configured to isolate said one or more batteries 102 from said direct current power 110 to facilitate maintenance, and said safety enclosure 120 encloses said battery safety switch 118 to permit secure manual or remote activation of battery isolation.

Said BMARS control module 104 can be configured for performing the battery load test 712 on said one or more batteries 102 at any point during normal operation, and thereby assessing the available capacity of each battery cell without interrupting power to said direct current power 110. Said battery safety switch 118 can be configured to isolate said one or more batteries 102 from said direct current power 110 to facilitate maintenance. And said safety enclosure 120 encloses said battery safety switch 118 to permit secure manual or remote activation of battery isolation.

The method of use 700 for operating the BMARS system 100 can comprise (a) initializing the battery monitoring step 702 to activate real-time tracking of battery parameters for one or more batteries one or more batteries 102, (b) monitoring said battery parameters at the monitoring battery parameters step 704, the battery parameters including at least one of voltage, temperature, and current, (c) determining whether said one or more batteries 102 require charging at the determining charging status step 706, (d) triggering the triggering charging mode adjustment step 708 to place the charger 108 in either Float mode or Equalize mode based on a condition of said one or more batteries 102, (e) continuing an equalization process at the continuing equalization step 710 until said one or more batteries 102 reach full charge, and (f) conducting the battery load test 712 to evaluate discharge response of said one or more batteries 102, wherein data from steps (b) through (f) can be logged at predefined time intervals and stored for subsequent analysis.

Generating and logging alarm conditions 714 when an abnormal parameter can be detected, including steps of: recording timestamped data indicating said abnormal parameter, and transmitting a notification The communication hardware 804.

Said battery load test 712 can be performed on said one or more batteries 102 without taking them offline, thereby verifying battery capacity in real time while maintaining power to the direct current power 110.

Said BMARS system 100 periodically checks a state of charge of said one or more batteries 102, automatically switching from Float mode to Equalize mode whenever the state of charge can be below about 80%, and returning to Float mode upon detecting full charge. Performing said battery load test 712 includes recommending that said charger 108 be set to Equalize mode for a designated duration, followed by switching to Float mode for final stabilization of charge levels.

Remotely monitoring and controlling charging states of said charger 108 at the remotely monitoring and control step 718 through the communication hardware 804, wherein the BMARS control module 104 logs all remote commands and resulting battery parameters in a data store accessible to the control panel 114.

Said BMARS system 100 automatically transitions to supply power from said one or more batteries 102 to the direct current power 110 upon detecting a utility outage, and subsequently maintains continuous logging of battery discharge events to track time-stamped data for predictive maintenance.

Various changes in the details of the illustrated operational methods are possible without departing from the scope of the following claims. Some embodiments may combine the activities described herein as being separate steps. Similarly, one or more of the described steps may be omitted, depending upon the specific operational environment the method is being implemented in. It is to be understood that the above description is intended to be illustrative, and not restrictive. For example, the above-described embodiments may be used in combination with each other. Many other embodiments will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.”

1. A BMARS system for maintaining and managing battery performance, wherein:
the term BMARS stands for battery monitoring and recharge system;
said BMARS system comprising
a BMARS control module configured to monitor, log, and manage one or more battery parameters,
a charger adapted to convert AC power to DC power,
a direct current power connected to said charger and adapted to supply DC power to at least one load,
a breaker interposed between said direct current power and
one or more batteries one or more batteries,
a battery safety switch housed in a safety enclosure,
one or more sensors one or more sensors configured to measure voltage, temperature, or current of said one or more batteries,
and a control panel communicatively coupled to said BMARS control module;
wherein said BMARS control module is configured to:
(a) automatically track a charging state of said one or more batteries,
(b) selectively switch between a Float mode and an Equalize mode for said charger,
(c) record performance data for said one or more batteries at predefined time intervals, and
(d) provide remote monitoring and control signals for battery maintenance;
said BMARS control module comprises an address space having:
one or more processors,
communication hardware, and
a memory storing instructions for
a device application,
an alarm system application, and
a notification system application;
said communication hardware is configured to exchange data with an external network, and
said alarm system application is programmed to generate an alarm upon detecting abnormal battery conditions selected from the group consisting of:
over-voltage, under-voltage, over-temperature, and under-temperature;
said BMARS system further comprises a hall effects sensor included among said one or more sensors,
the hall effects sensor being arranged to measure both charging current flowing from said charger to said one or more batteries and load current drawn from said one or more batteries to said direct current power.

2. A BMARS system for maintaining and managing battery performance, wherein:
the term BMARS stands for battery monitoring and recharge system;
said BMARS system comprising
a BMARS control module configured to monitor, log, and manage one or more battery parameters,
a charger adapted to convert AC power to DC power,
a direct current power connected to said charger and adapted to supply DC power to at least one load,
a breaker interposed between said direct current power and
one or more batteries one or more batteries,
a battery safety switch housed in a safety enclosure,
one or more sensors one or more sensors configured to measure voltage, temperature, or current of said one or more batteries,
and a control panel communicatively coupled to said BMARS control module;
wherein said BMARS control module is configured to:
(a) automatically track a charging state of said one or more batteries,
(b) selectively switch between a Float mode and an Equalize mode for said charger,
(c) record performance data for said one or more batteries at predefined time intervals, and
(d) provide remote monitoring and control signals for battery maintenance.

3. The BMARS system of claim 1, wherein
said BMARS control module comprises the address space having:
one or more processors,
communication hardware, and
The memory storing instructions for
The device application,
an alarm system application, and
The notification system application;
said communication hardware is configured to exchange data with an external network, and
said alarm system application is programmed to generate an alarm upon detecting abnormal battery conditions selected from the group consisting of:
over-voltage, under-voltage, over-temperature, and under-temperature.

4. The BMARS system of claim 3, wherein
said BMARS system further comprises a software interface,
said software interface presenting real-time graphical displays of battery status, cell voltages, cell temperatures, charge current, and load current.

5. The BMARS system of claim 4, wherein:
said software interface includes a battery status screen adapted to show a user-selectable option for initiating a battery load test and retrieving logged performance data.

6. The BMARS system of claim 1, wherein
said BMARS system further comprises the hall effects sensor included among said one or more sensors,
the hall effects sensor being arranged to measure both charging current flowing from said charger to said one or more batteries and load current drawn from said one or more batteries to said direct current power.

7. The BMARS system of claim 1, wherein
the rolling data comprising timestamped measurements of voltage, temperature, and charge or discharge current.

8. The BMARS system of claim 7, wherein
said BMARS control module is configured to maintain about three years of rolling data for said one or more batteries.

9. The BMARS system of claim 1, wherein
said BMARS control module is configured for
performing a battery load test on said one or more batteries at any point during normal operation, and
thereby assessing the available capacity of each battery cell without interrupting power to said direct current power.

10. The BMARS system of claim 1, wherein
said battery safety switch is configured to isolate said one or more batteries from said direct current power to facilitate maintenance,
and said safety enclosure encloses said battery safety switch to permit secure manual or remote activation of battery isolation.

11. The BMARS system of claim 1, wherein
said BMARS control module is configured for
performing a battery load test on said one or more batteries at any point during normal operation, and
thereby assessing the available capacity of each battery cell without interrupting power to said direct current power;
said battery safety switch is configured to isolate said one or more batteries from said direct current power to facilitate maintenance; and
and said safety enclosure encloses said battery safety switch to permit secure manual or remote activation of battery isolation.

12. A method of use for operating a BMARS system, comprising:
(a) initializing a battery monitoring step to activate real-time tracking of battery parameters for one or more batteries one or more batteries,
(b) monitoring said battery parameters at a monitoring battery parameters step, the battery parameters including at least one of voltage, temperature, and current,
(c) determining whether said one or more batteries require charging at a determining charging status step,
(d) triggering a triggering charging mode adjustment step to place a charger in either Float mode or Equalize mode based on a condition of said one or more batteries,
(e) continuing an equalization process at a continuing equalization step until said one or more batteries reach full charge, and
(f) conducting a battery load test to evaluate discharge response of said one or more batteries,
wherein data from steps (b) through (f) is logged at predefined time intervals and stored for subsequent analysis.

13. The method of use of claim 12, further comprising:
generating and logging alarm conditions when an abnormal parameter is detected, including steps of:
recording timestamped data indicating said abnormal parameter, and
transmitting a notification via communication hardware.

14. The method of use of claim 12, wherein:
said battery load test is performed on said one or more batteries without taking them offline,
thereby verifying battery capacity in real time while maintaining power to a direct current power.

15. The method of use of claim 12, wherein:
said BMARS system periodically checks a state of charge of said one or more batteries,
automatically switching from Float mode to Equalize mode whenever the state of charge is below about 80%,
and returning to Float mode upon detecting full charge.

16. The method of use of claim 12, wherein:
performing said battery load test includes recommending that said charger be set to Equalize mode for a designated duration,
followed by switching to Float mode for final stabilization of charge levels.

17. The method of use of claim 12, further comprising:
remotely monitoring and controlling charging states of said charger at a remotely monitoring and control step through a communication hardware,
wherein a BMARS control module logs all remote commands and resulting battery parameters in a data store accessible to a control panel.

18. The method of use of claim 12, wherein:
said BMARS system automatically transitions to supply power from said one or more batteries to a direct current power upon detecting a utility outage,
and subsequently maintains continuous logging of battery discharge events to track time-stamped data for predictive maintenance.
